(19) United States
(12) Patent Application Publication
(10) Pub. No.: US 2011/0186225 A1
(43) Pub. Date: Aug. 4, 2011

(54) MAGNETIC RECORDING MEDIUM MANUFACTURING DEVICE

(75) Inventors: Tsutomu Nishihashi, Shizuoka (JP); Tadashi Morita, Ibaraki (JP); Kazuhiro Watanabe, Shizuoka (JP); Kenji Sato, Kanagawa (JP); Takuya Uzumaki, Kanagawa (JP); Tsutomu Tanaka, Kanagawa (JP)

(73) Assignee: ULVAC, INC., Kanagawa (JP)

(21) Appl. No.: 13/055,329

(22) PCT Filed: Jul. 21, 2009
(86) PCT No.: PCT/JP2009/003404

§ 371 Date: Apr. 18, 2011

(30) Foreign Application Priority Data
Jul. 22, 2008 (JP) 2008-188466

(51) Int. Cl. H01L 21/3065

(52) U.S. Cl. 156/345.31

(57) ABSTRACT

A magnetic recording medium is manufactured without the disappearance of the surface of a substrate that comprises a magnetic recording layer by ion milling and without being influenced by the atmosphere. A magnetic recording medium manufacturing device manufactures a magnetic recording medium by implanting an ion beam into a substrate that comprises a magnetic recording layer and removing by ashing the surface of the substrate that comprises the magnetic recording layer after the ion beam is implanted. The magnetic recording medium manufacturing device comprising an ion implantation chamber for implanting the ion beam into the substrate that comprises the magnetic recording layer coated with a resist film or a metal mask, and an ashing chamber for removing, by ashing, with plasma, the resist film or the metal mask of the substrate that comprises the magnetic recording layer coated with the resist film or the metal mask. The ion implantation chamber and the ashing chamber are coupled in a vacuum state. The magnetic recording medium manufactured device is provided with a substrate carrier for carrying the substrate into which the ion beam is implanted from the ion implantation chamber to the ashing chamber.

### FIELD OF THE INVENTION

The present invention relates to a magnetic recording medium manufacturing device for manufacturing a high density magnetic recording medium.

### BACKGROUND

In a conventional method for manufacturing a magnetic recording medium, a magnetic layer is etched in accordance with a resist pattern formed on the magnetic layer by using plasma or an ion beam at first, and then a groove in the etched magnetic layer is filled with a non-magnetic material. Next, after flattening a surface of the magnetic layer through a flattening process, such as ion beam etching and polishing, a protective film is formed on the surface (For example, refer to Patent Document 1).

Using the method of manufacturing a magnetic recording medium, disclosed in Patent Document 1, requires steps of filling with a non-magnetic material and flattening the surface of the magnetic layer after etching an area other than an information recording area for removal, so that the manufacturing process becomes complicated. Accordingly, this also results in another unfavorable effect that the production cost increases.

As a method for solving the unfavorable issues described above, proposed is a method, in which ions are locally implanted into a magnetic film to change a magnetization state there, and afterwards an entire surface of the magnetic film is annealed (For example, refer to Patent Document 2).

### PRIOR ART DOCUMENTS

### Patent Documents

Patent Document 1: JP2003-16621A (FIG. 3)
Patent Document 2: JP2005-228817A (FIG. 1)

### SUMMARY OF INVENTION

### Problems to be Solved

However, in the method of manufacturing a magnetic recording medium disclosed in Patent Document 2, it is required to implant high-density ions within a density range from 1×10¹⁶ ions/cm² to 1×10¹⁹ ions/cm² for changing a composition ratio of atomic elements in a magnetic film. Accordingly, there exists a risk that a resist film and a protective film may disappear, and a further risk that a magnetic film may also disappear owing to ion beam milling. Meanwhile, since a substrate is externally transferred when being moved among manufacturing processes, the substrate exposes itself to the atmosphere so that unfortunately deterioration in quality happens.

Thus, it is an object of the present invention to provide a magnetic recording medium manufacturing device that can manufacture a magnetic recording medium with neither any disappearance of a resist film, a protective film, and a magnetic film owing to ion beam milling, nor any effect of the atmosphere.

### Means to Solve the Problems

To achieve the object described above, the present invention provides the following aspect; i.e., a magnetic recording medium manufacturing device for manufacturing a magnetic recording medium through steps of dosing an ion beam into a substrate having a magnetic recording layer, and ashing and removing at least one of a resist film and a metal mask on a surface of the substrate having the magnetic recording layer after the ion beam dosing; the magnetic recording medium manufacturing device including: an ion implantation chamber, to which a required kind of ions are supplied from a source of ion supply for generating ions; the ions being accelerated to have an energy as required, and the ion beam then being dosed into a substrate having a magnetic recording layer created by applying one of a resist film and a metal mask; and an ashing chamber equipped with a plasma generator for generating and diffusing plasma; in the ashing chamber, at least one of the resist film and the metal mask being ashed and removed by using the plasma diffused with the plasma generator, from the substrate having the magnetic recording layer created by applying one of the resist film and the metal mask; wherein, the ion implantation chamber and the ashing chamber are connected with a vacuum valve under vacuum condition, and the magnetic recording medium manufacturing device is equipped with a substrate carrier for carrying the substrate from the ion implantation chamber to the ashing chamber after the ion beam dosing.

According to the structure described above, the ion implantation chamber and the ashing chamber are connected with the vacuum valve under the vacuum condition. Therefore, the substrate having the magnetic recording layer can be processed continuously without exposing itself to the atmosphere at an inter-process point between the ion implantation and the ashing. Accordingly, this arrangement makes it possible to avoid a quality deterioration of the magnetic recording medium owing to a bad effect of the atmosphere.

In addition to the above aspect, it is preferable that the magnetic recording medium manufacturing device further includes a CVD (Chemical Vapor Deposition) chamber for forming a thin film on a surface of the substrate, having the magnetic recording layer after the ashing, by means of generating plasma through applying a high-frequency power to one of a parallel plate electrode and an inductive coupling antenna; wherein the ashing chamber and the CVD chamber are connected with a vacuum valve under vacuum condition, and the substrate carrier carries the substrate having the magnetic recording layer after the ashing from the ashing chamber to the CVD chamber.

According to the structure described above, the magnetic recording medium manufacturing device makes it possible to form a protective film on a surface of the substrate. Therefore, it becomes possible to avoid damage of the magnetic recording medium due to a defect, and also to surely avoid a quality deterioration of the magnetic recording medium owing to a bad effect of the atmosphere.

In addition to the above aspect, it is preferable that furthermore the substrate carrier includes; a substrate holder for holding the substrate; and a driving mechanism for driving the substrate holder.

According to the structure described above, the substrate having the magnetic recording layer can smoothly be transferred to a next process chamber.

### Advantageous Effect of the Invention

According to the present invention, a magnetic recording medium can be manufactured with neither any disappearance of a surface of a substrate, including a magnetic recording layer, owing to ion milling, nor any effect of the atmosphere. Furthermore, a manufacturing process according to the present invention is simplified in comparison with the manufacturing method described in Patent Document 1 so as to enable cost reduction.

### BRIEF DESCRIPTION OF THE DRAWINGS

FIG. 1 is a side view drawing for explaining a structural overview of a magnetic recording medium manufacturing device according to an embodiment of the present invention.

FIG. 2 is a cross sectional view of the magnetic recording medium manufacturing device taken along the line A-A of FIG. 1.

FIGS. 3A and 3B show a structure of a substrate carrier of FIG. 1; namely FIG. 3A is a side view drawing of the substrate carrier, and FIG. 3B is a cross sectional view of the substrate carrier taken along the line B-B of FIG. 3A.

FIG. 4 is a cross sectional view of an ion implantation chamber taken along the line C-C of FIG. 1.

FIG. 5 is a cross sectional view of an ashing chamber taken along the line D-D of FIG. 1.

FIG. 6 is a cross sectional view of a CVD chamber taken along the line E-E of FIG. 1.

FIGS. 7A to 7D are drawings for explaining processes of manufacturing a magnetic recording medium by using the magnetic recording medium manufacturing device according to an embodiment of the present invention; namely, FIG. 7A is a cross sectional view for explaining an ion implantation, FIG. 7B is a cross sectional view of a substrate having a resist film after the ion implantation, FIG. 7C is a cross sectional view of a substrate having a magnetic recording layer after an ashing operation, and FIG. 7D is a cross sectional view of a magnetic recording medium.

### DESCRIPTION OF THE PREFERRED EMBODIMENT

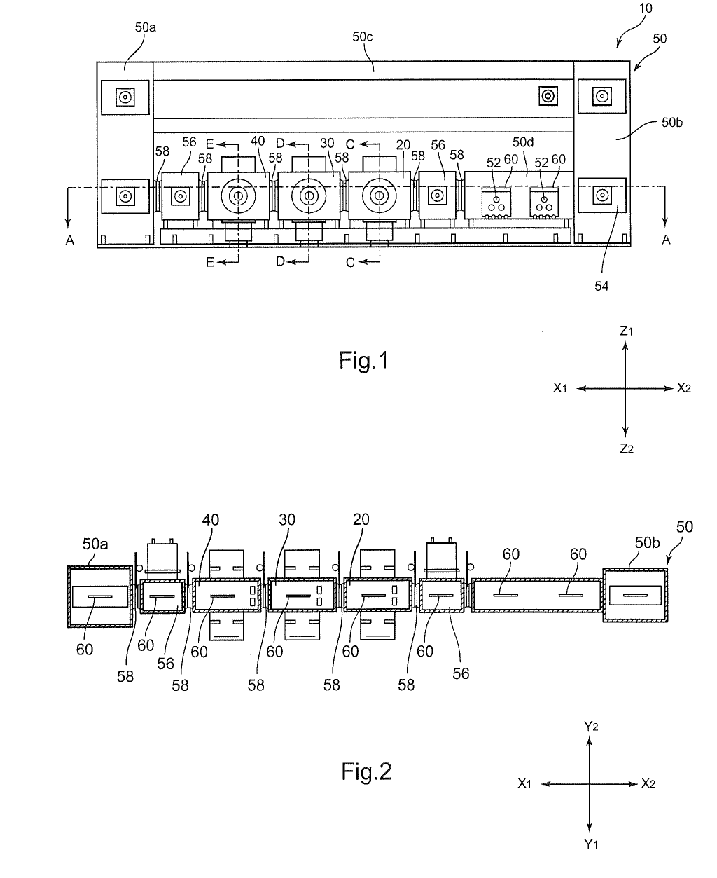

A magnetic recording medium manufacturing device 10 according to an embodiment of the present invention is described below with reference to the accompanied drawings. In the following explanation, each direction shown in FIGS. 1 to 6 represents its corresponding direction as described below: Directions of arrows X1 and X2 represent the front and the rear, respectively. Directions of arrows Y1 and Y2, which are perpendicular to the directions of the arrows X1 and X2 in a horizontal direction, represent the left and the right, respectively. Directions of arrows Z1 and Z2, which are perpendicular to the X-Y plane, represent the top and the bottom, respectively.

FIG. 1 is a side view drawing for explaining a structural overview of the magnetic recording medium manufacturing device 10 according to the embodiment of the present invention. FIG. 2 is a cross sectional view of the magnetic recording medium manufacturing device 10 taken along the line A-A of FIG. 1.

As shown in FIG. 1 and FIG. 2, the magnetic recording medium manufacturing device 10 is an endless in-line type apparatus, in which connected in series are an ion implantation chamber 20, an ashing chamber 30, and a CVD chamber 40 (when the ion implantation chamber 20, the ashing chamber 30, and the CVD chamber 40 are referred to collectively, these chambers are simply called the “process chambers 20, 30, and 40”) and a substrate transfer passage 50 interconnects these chambers externally. The magnetic recording medium manufacturing device 10 is equipped with a substrate carrier 60 for carrying a substrate including a magnetic recording layer (hereinafter, a substrate before and after a processing operation in the process chambers 20, 30, and 40 is collectively called a substrate 52). In the meantime, the substrate 52 taken in at a start point 54 is processed through the process chambers 20, 30, and 40 for each processing operation, and then the substrate 52 is transported back to the start point 54.

A load lock chamber 56 is each placed at the rear of the ion implantation chamber 20 and in front of the CVD chamber 40. Each load lock chamber 56 is used for a preparatory vacuuming operation in order to avoid the air from entering the process chambers 20, 30, and 40, before the substrate carrier 60 with the substrate 52 is introduced from the substrate transfer passage 50, having the atmospheric environment, into the process chambers 20, 30, and 40 under vacuum condition. The ion implantation chamber 20, the ashing chamber 30, the CVD chamber 40, a front vertical passage 50a to be described later, a bottom horizontal passage 50d to be described later, and each load lock chamber 56 are connected one another by means of a connecting part 58 so as to be airtight. Though being not shown in FIG. 1, each connecting part 58 for connecting the process chambers 20, 30, and 40 and the load lock chamber 56 is equipped with a shutter valve working as a vacuum valve.

The substrate transfer passage 50 includes the front vertical passage 50a, a rear vertical passage 50b, a top horizontal passage 50c, and the bottom horizontal passage 50d. These passages are circularly connected so as to interconnect one load lock chamber 56 with the other load lock chamber 56 for making up an endless circuit (Refer to FIG. 1). All of the front vertical passage 50a, the rear vertical passage 50b, the top horizontal passage 50c, and the bottom horizontal passage 50d are tubular and box-shaped in their cross section. The front vertical passage 50a is placed at a further front position from the load lock chamber 56 installed in front of the CVD chamber 40. A lower part of the front vertical passage 50a is connected to the load lock chamber 56 through the connecting part 58. Facing the front vertical passage 50a, the rear vertical passage 50b is placed in front of the ion implantation chamber 20. The start point 54 is placed, for example, at a lower position of the rear vertical passage 50b. The top horizontal passage 50c connects upper parts of the front vertical passage 50a and the rear vertical passage 50b in a horizontal direction. The bottom horizontal passage 50d connects the load lock chamber 56 installed at the rear of the ion implantation chamber 20 to a lower part of the rear vertical passage 50b in a horizontal direction. In the meantime, being provided in plurality, substrate carriers 60 are placed, for example, inside the process chambers 20, 30, and 40 as well as the substrate transfer passage 50 at predetermined intervals.

Described below next is a structure of a substrate carrier 60.

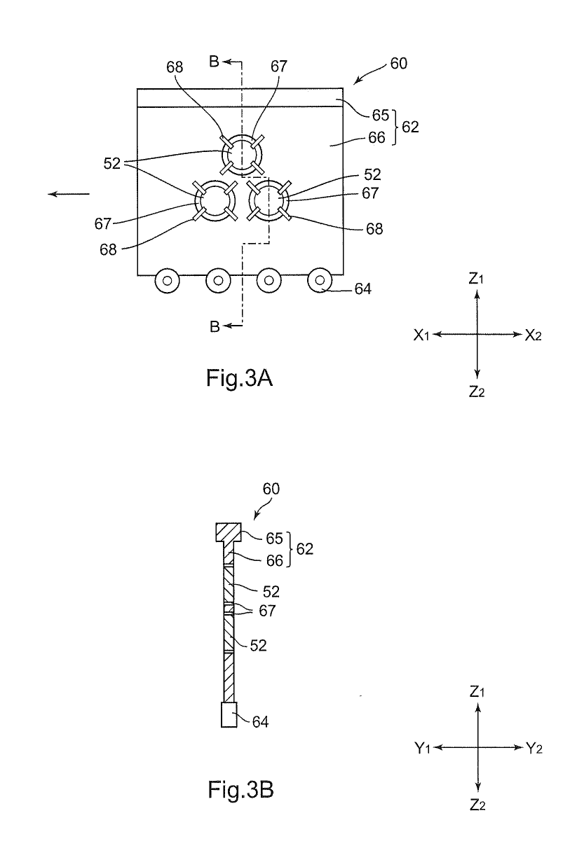

FIGS. 3A and 3B show the structure of the substrate carrier 60; namely FIG. 3A is a side view drawing of the substrate carrier 60, and FIG. 3B is a cross sectional view of the substrate carrier 60 taken along the line B-B of FIG. 3A.

As FIGS. 3A and 3B show, the substrate carrier 60 includes a substrate holder 62 for holding the substrate 52, and driving rollers 64 of a driving mechanism for driving the substrate holder 62. The substrate holder 62 includes a protrusion 65, which protrudes in a horizontal direction at an upper part of the substrate holder 62 (Refer to FIG. 3B), and a flat plate section 66 that is almost flat. Then, the substrate holder 62 has its cross-section being almost T-shaped. Placed almost at the center of the flat plate section 66 are 3 circular bores 67 penetrating horizontally through the flat plate section 66. The circular bores 67 are each placed at positions corresponding to 3 corners of an equilateral triangle. Then, each of the circular bores 67 in the flat plate section 66 is equipped with substrate clamps 68 at its outer edge part for holding a substrate 52. The substrate clamps 68 for each of the circular bores 67 are each laid out at diagonal positions of 4 corners of a square internally touching an inside wall of the circular bore 67. The substrate 52 having a disc-like shape is placed inside the circular bore 67. Then, the substrate clamps 68 clamp an outer circumferential area of the substrate 52 to retain the substrate 52 in the substrate holder 62. When the substrate 52 is retained in the substrate holder 62, both surfaces of the substrate 52 are arranged so as to be almost in parallel with a Z-X plane of the substrate holder 62.

The driving rollers 64, for example 4 sets in number, are laid out at a bottom of the substrate holder 62 in a back-and-forth direction. When the driving rollers 64 rotate, the substrate holder 62 moves backward and forward. Through controlling rotation movement of the driving rollers 64 by a control device, not shown in the drawing, movement of the substrate carrier 60 is controlled.

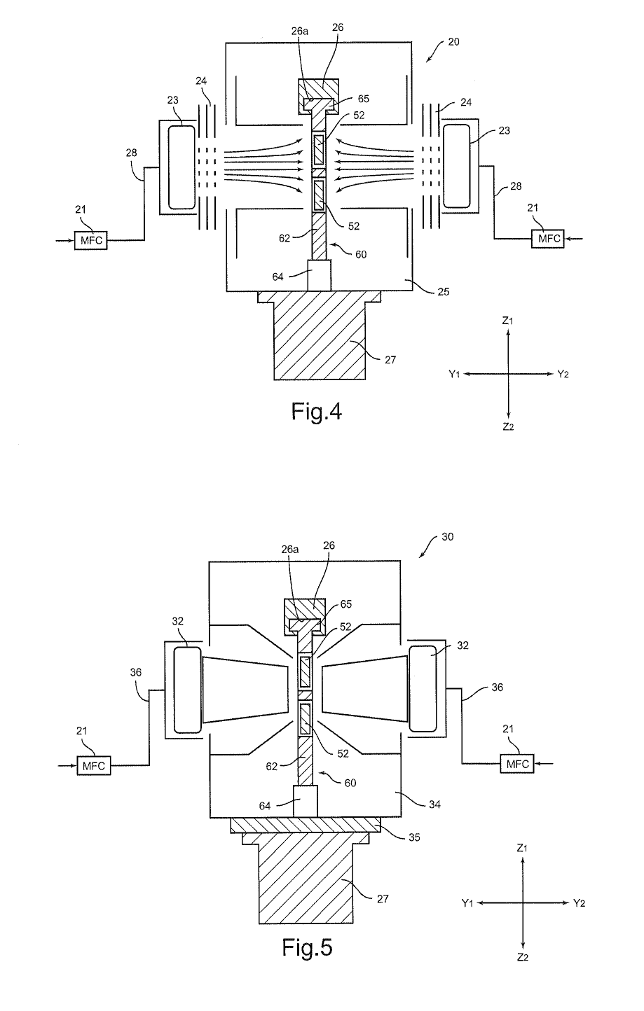

Explained next with reference to FIG. 4 is a structure of the ion implantation chamber 20. FIG. 4 is a cross sectional view of the ion implantation chamber taken along the line C-C of FIG. 1.

As shown in FIG. 4, the ion implantation chamber 20 principally includes a mass flow controller (MFC) 21 for blowing off process gas while controlling the gas blowing operation, an ion generator 23 that generates and diffuses ions while controlling the amount of ions to be generated, an accelerating electrode 24 for regulating the diffusion and energy of the ions, a substrate storage section 25 for storing the substrate carrier 60, a substrate holding section 26 for holding the substrate carrier 60, and a vacuum pump 27 for discharging a residual gas out of the ion implantation chamber 20 externally.

Each of both left and right sides of the substrate storage section 25 is provided with one MFC 21, one ion generator 23, and one accelerating electrode 24. The MFC 21 regulates the amount of process gas that is supplied from a process gas supply source, not shown in the drawing, into the ion generator 23. The MFC 21 and the ion generator 23 are so connected with a tube 28 that the process gas is fed from the MFC 21 through the tube 28 to the ion generator 23. The ion generator 23 generates the ions according to the supplied process gas, and regulates the amount of ions and its spatial distribution. Then, the accelerating electrode 24 blows off and accelerates the ions, for example with a voltage within the range of 20 KV to 30 KV. Thus, the accelerated ions are dosed from the ion generator 23 and the accelerating electrode 24 into the substrate 52 as an ion beam.

The substrate holding section 26 is placed in an upper area of the substrate storage section 25, being almost at a center position in an Y1-Y2 direction of the substrate storage section 25. Provided at a bottom section of the substrate holding section 26 is an engaging groove 26a prepared by cutting out a part upward in a back-and-forth direction. While a protrusion part 65 of the substrate holder 62 being in engagement with the engaging groove 26a under contact-free condition, the substrate holder 62 is held almost at a center position of the ion implantation chamber 20. Then, an ion beam is radiated toward the substrate 52 held by the substrate holder 62 to accomplish ion implantation. A residual gas remaining inside the substrate storage section 25 after the ion implantation is discharged externally by the vacuum pump 27.

Explained next with reference to FIG. 5 is a structure of the ashing chamber 30. FIG. 5 is a cross sectional view of the ashing chamber 30 taken along the line D-D of FIG. 1.

As shown in FIG. 5, the ashing chamber 30 principally includes an MFC 21, a plasma generator 32 that generates and diffuses plasma, a substrate storage section 34 for storing the substrate carrier 60 sent out of the ion implantation chamber 20, a substrate holding section 26, a vacuum pump 27, and a conductance-variable valve 35.

Each of both left and right sides of the substrate storage section 34 is provided with one MFC 21, and one plasma generator 32. An appropriate amount of process gas regulated by the MFC 21 is supplied from a process gas supply source, not shown in the drawing, to the plasma generator 32. As the process gas for an ashing operation, a commonly used oxygen-based or fluorine-based single-component gas or a mixed gas including those components can be used. The MFC 21 and the plasma generator 32 are so connected with a tube 36 that the process gas is fed from the MFC 21 through the tube 36 to the plasma generator 32. In the plasma generator 32, the fed process gas is excited by a high-frequency wave to generate plasma, and then the generated plasma is diffused toward a center of the substrate storage section 34. Thus, the plasma is radiated to the substrate 52 held by the substrate holding section 26 to perform ashing for a resist film on the substrate 52. Then, after the ashing operation, a gas inside the substrate storage section 34 is externally exhausted by the vacuum pump 27. The conductance-variable valve 35 placed between the vacuum pump 27 and the substrate storage section 34 controls an effective exhausting speed of the exhaust out of the vacuum pump 27 to control a partial pressure inside the substrate storage section 34. Connected to the substrate holding section 26 of the ashing chamber 30 is a bias applying power supply which is able to apply a substrate bias to the substrate holder 62 held by the substrate holding section 26, the bias applying power supply being not shown in the drawing. Then, energy of the plasma radiated to the substrate 52 can be controlled by means of controlling the substrate bias to the substrate holder 62.

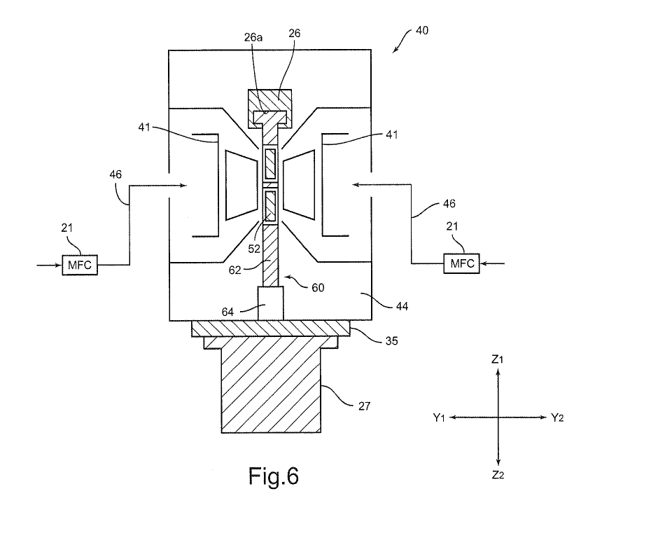

Explained next with reference to FIG. 6 is a structure of the CVD chamber 40. FIG. 6 is a cross sectional view of the CVD chamber 40 taken along the line E-E of FIG. 1.

As shown in FIG. 6, the CVD chamber 40 principally includes an MFC 21, a plate electrode 41 installed in a substrate storage section 44, the substrate storage section 44 for storing the substrate carrier 60 sent out of the ashing chamber 30, a substrate holding section 26, a vacuum pump 27, and a conductance-variable valve 35.

Each of both left and right sides of the substrate storage section 44 is provided with one MFC 21, and one plate electrode 41. A high-frequency power is applied through a high-frequency power supply, not shown in the drawing, to each plate electrode 41. In the meantime, an appropriate amount of process gas regulated by the MFC 21 is supplied from a process gas supply source, not shown in the drawing, to the substrate storage section 44. Furthermore, while the substrate holding section 26 being connected to a ground potential, connected to the substrate holder 62 held by the substrate holding section 26 is a bias applying power supply which is able to apply a substrate bias, the bias applying power supply being not shown in the drawing. Then, a film forming performance is controlled through controlling the substrate bias applied to the substrate holder 62. As the process gas for a CVD operation, a commonly used carbon-based gas mixture can be used. The MFC 21 and the substrate storage section 44 are so connected with a tube 46 that the process gas is introduced from the MFC 21 through the tube 46 to the substrate storage section 44. Under the condition, when the high-frequency power is applied to the plate electrode 41, the process gas introduced from the MFC 21 to the substrate storage section 44 discharges between the substrate holder 62 and the plate electrode 41 to become plasma in the substrate storage section 44. The process gas energized into plasma reaches a surface of the substrate 52, which is held by the substrate holding section 26 at a center of the substrate storage section 44, to form a thin film on the substrate 52 as expected. Then, after the film forming operation, the gas inside the substrate storage section 44 is externally exhausted by the vacuum pump 27. In the meantime, connected to the substrate holding section 26 of the CVD chamber 40 is a bias applying power supply which is able to apply a substrate bias to the substrate holder 62 held by the substrate holding section 26, the bias applying power supply being not shown in the drawing. Then, characteristics of the thin film formed on the substrate 52 can be controlled by means of controlling the substrate bias to the substrate holder 62.

Explained next is a series of processes for manufacturing a magnetic recording medium 70 by using the magnetic recording medium manufacturing device 10.

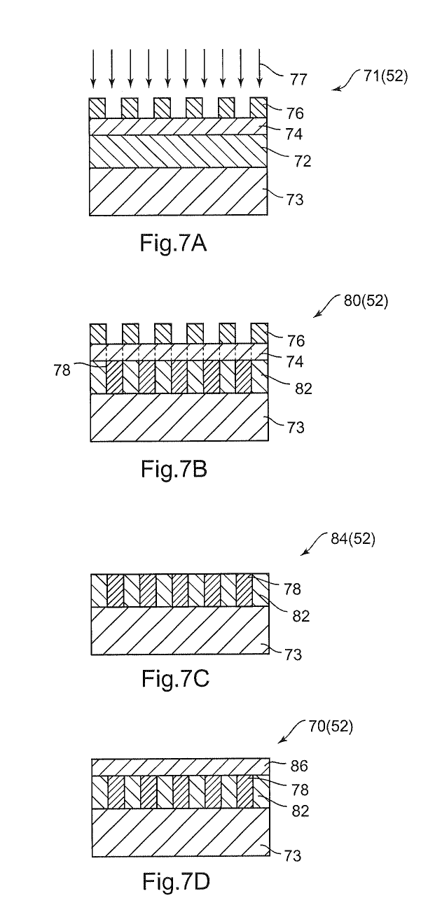

FIGS. 7A to 7D are drawings for explaining processes of manufacturing the magnetic recording medium 70 by using the magnetic recording medium manufacturing device 10; namely, FIG. 7A is a cross sectional view for explaining an ion implantation, FIG. 7B is a cross sectional view of a substrate 80 having a resist film after the ion implantation, FIG. 7C is a cross sectional view of a substrate 84 having a magnetic recording layer after an ashing operation, and FIG. 7D is a cross sectional view of a magnetic recording medium 70.

At first, a substrate with a resist film 71; in which a magnetic film 72, a protective film 74, and a resist film 76 are laminated in this order on a base substrate 73 shown in FIG. 7A; is placed into the substrate carrier 60 by using a transfer device at the start point 54 shown in FIG. 1. The placement of the substrate with a resist film 71 into the substrate carrier 60 is carried out through holding the substrate with a resist film 71 by using the substrate holder 62, as described above. The substrate with a resist film 71 has its contour shaped almost like a disc in the same manner as the base substrate 73 has. Used as the base substrate 73 is, for example, a nonmagnetic substrate such as an aluminum alloy substrate, a silicon glass substrate, and the like. Preferably, the magnetic film 72 should be provided with an ordered structure having a high magnetic anisotropy. The protective film 74 is a coating film, for example, made of diamond like carbon and so on. The resist film 76 is a thin film of a resist material having a certain pattern.

The substrate with a resist film 71 is placed into the substrate carrier 60, and then the substrate carrier 60 passes through the bottom horizontal passage 50d shown in FIG. 1, and arrives at the load lock chamber 56. After the pressure inside the load lock chamber 56 is lowered through vacuum evacuation down to a pressure level that does not significantly affect the pressure inside the ion implantation chamber 20, the substrate carrier 60 passes through the load lock chamber 56 and moves into the ion implantation chamber 20, if the load lock chamber 56 is opened. Then, engaging with the substrate holding section 26 in the ion implantation chamber 20, the substrate carrier 60 is held almost at a center of the ion implantation chamber 20. Subsequently, an ion beam 77 from the ion generator 23 is radiated to a surface of the substrate with a resist film 71 for ion implantation (Refer to FIG. 7A). As the ion implantation is carried out into the surface of the substrate with a resist film 71, a magnetic force decreases at a part with implantation 78 where the ion implantation is carried out through an opening area of the resist film 76, as shown in FIG. 7B.

Next, the substrate carrier 60 moves from the ion implantation chamber 20 through the connecting part 58, shown in FIG. 1, into the ashing chamber 30. Then, engaging with the substrate holding section 26 in the ashing chamber 30, the substrate carrier 60 is held almost at a center of the ashing chamber 30. Subsequently, the plasma from the plasma generator 32 is radiated to a surface of a substrate with an ion-implanted resist film 80 for ashing and removing the resist film 76 and the protective film 74. As a result, formed is a substrate with a magnetic recording layer 84; in which a characteristic magnetic film 82 having a certain magnetic characteristics is laminated on the base substrate 73, as shown in FIG. 7C.

Next, the substrate carrier 60 moves from the ashing chamber 30 through the connecting part 58, shown in FIG. 1, into the CVD chamber 40. Then, engaging with the substrate holding section 26 in the a CVD chamber 40, the substrate carrier 60 is held almost at a center of the CVD chamber 40. Subsequently, while a process gas is supplied to the substrate storage section 44, a high-frequency power is applied to the plate electrode 41, so that the supplied process gas is energized into plasma inside the substrate storage section 44. Then, the process gas energized into plasma is radiated to the substrate with a magnetic recording layer 84 to form a CVD protective film 86 having a flat surface on the substrate with a magnetic recording layer 84. According to those processes described above, manufactured is the magnetic recording medium 70 in which the CVD protective film 86 is laminated on the substrate with a magnetic recording layer 84, as shown in FIG. 7D.

Next, under the condition that the pressure inside the load lock chamber 56 is equal to the atmospheric pressure, the substrate carrier 60 holding the magnetic recording medium 70 passes through the load lock chamber 56 and moves to the front vertical passage 50a. Furthermore, as the substrate carrier 60 moves from the front vertical passage 50a through the top horizontal passage 50c to the rear vertical passage 50b, the magnetic recording medium 70 is transferred back to the start point 54. Then, being dismounted out of the substrate carrier 60 by using the transfer device at the start point 54, the magnetic recording medium 70 can be removed from the magnetic recording medium manufacturing device 10.

In the magnetic recording medium manufacturing device 10 structured as described above, the ion implantation chamber 20, the ashing chamber 30, as well as the CVD chamber 40 are connected in series under the vacuum condition so that the processes of the ion implantation, the ashing and the CVD can be carried out continuously without any contact with the atmosphere. Therefore, this arrangement makes it possible to avoid a quality deterioration of the magnetic recording medium 70 owing to a bad effect of the atmosphere.

Furthermore, the magnetic recording medium manufacturing device 10 makes it possible to form the CVD protective film 86 on a surface of the substrate 52. Accordingly, it becomes possible to avoid damage of the magnetic recording medium 70 due to a defect, and also to surely avoid a quality deterioration of the magnetic recording medium 70 owing to a bad effect of the atmosphere.

Moreover, in the magnetic recording medium manufacturing device 10, the substrate 52 is transferred into the process chambers 20, 30, and 40 while being held by the substrate carrier 60. Therefore, when being transferred, the substrate 52 exposes its surfaces in the substrate holder 62 in a right-angle direction in relation to its moving direction. Accordingly, the substrate 52 can be set ready for processing instantly by simply holding the transferred substrate carrier 60 in the process chambers 20, 30, and 40.

With respect to the embodiment according to the present invention as described above, the present invention is not limited to the above embodiment and various other variations may be made.

In the above embodiment, the substrate transfer passage 50 is so placed as to be circular in a vertical plane in relation to the process chambers 20, 30, and 40. Alternatively, instead of the placement of the passage in a vertical plane, the substrate transfer passage 50 may as well be placed to be circular in a horizontal plane. Furthermore, the magnetic recording medium manufacturing device 10 may be prepared in any arrangement other than such a circular inline mode.

In the above embodiment, the substrate carrier 60 is driven by the driving rollers 64. Since the present invention is not limited to such an arrangement, alternatively possible may be another arrangement in which, for example, a line is placed in the magnetic recording medium manufacturing device 10 and the substrate carrier 60 moves along the line. Furthermore, in the above embodiment, the number of substrates, i.e., the substrate 52 provided in plurality, to be held in the substrate carrier 60 at the same time is 3. Alternatively, the number of substrates may be 2 or less, or 4 or more, instead of the number of substrates at 3.

In the above embodiment, the substrate carrier 60 is held in the process chambers 20, 30, and 40 by means of the engagement with the substrate holding section 26. Since the holding method is not limited to such engagement, alternatively the substrate carrier 60 may be held in the process chambers 20, 30, and 40 by any other method.

In the above embodiment, a mono-atomic ion beam is adopted. Since the type of ion beams is not limited to that of such a mono-atomic ion beam, alternatively adopted may be for example a cluster ion beam that includes a number of atoms in a bunch.

The ion implantation chamber 20, the ashing chamber 30, and the CVD chamber 40 are connected in series in the above embodiment. Instead, adopted may be another arrangement in which a processing chamber for preheating or cooling the substrate 52 is placed among the process chambers 20, 30, and 40. Furthermore, a buffer chamber for controlling the pressure in the process chambers 20, 30, and 40 may as well be placed.

In the above embodiment, the plasma is generated in the CVD chamber 40 by means of applying a high-frequency power to the plate electrode 41. Alternatively, a loop-shaped inductive coupling antenna may be placed instead of the plate electrode 41 to generate inductive coupling high-frequency plasma by means of applying a high-frequency power to the antenna.

### INDUSTRIAL APPLICABILITY

The magnetic recording medium manufacturing device according to the present invention can be applied in various electronic industries using semiconductors.

### REFERENCE NUMERALS

10. Magnetic recording medium manufacturing device
20. Ion implantation chamber
30. Ashing chamber
32. Plasma generator
40. CVD chamber
41. Plate electrode (parallel plate electrode)
60. Substrate carrier
62. Substrate holder
64. Driving rollers (driving mechanism)
70. Magnetic recording medium (substrate)
71. Substrate with a resist film (substrate)
76. Resist film
80. Substrate with an ion-implanted resist film (substrate)
86. CVD protective film (thin film)

1. A magnetic recording medium manufacturing device for manufacturing a magnetic recording medium through steps of dosing an ion beam into a substrate having a magnetic recording layer, and ashing and removing at least one of a resist film and a metal mask on a surface of the substrate having the magnetic recording layer after the ion beam dosing; the magnetic recording medium manufacturing device comprising:
an ion implantation chamber, to which a required kind of ions are supplied from a source of ion supply for generating ions; the ions being accelerated to have an energy as required, and the ion beam then being dosed into a substrate having a magnetic recording layer created by applying one of a resist film and a metal mask; and
an ashing chamber equipped with a plasma generator for generating and diffusing plasma; in the ashing chamber, at least one of the resist film and the metal mask being ashed and removed by using the plasma diffused with the plasma generator, from the substrate having the magnetic recording layer created by applying one of the resist film and the metal mask;
wherein, the ion implantation chamber and the ashing chamber are connected with a vacuum valve under vacuum condition, and the magnetic recording medium manufacturing device is equipped with a substrate carrier for carrying the substrate from the ion implantation chamber to the ashing chamber after the ion beam dosing.

2. The magnetic recording medium manufacturing device according to claim 1:
further comprising a CVD (Chemical Vapor Deposition) chamber for forming a thin film on a surface of the substrate, having the magnetic recording layer after the ashing, by means of generating plasma through applying a high-frequency power to one of a parallel plate electrode and an inductive coupling antenna;
wherein the ashing chamber and the CVD chamber are connected with a vacuum valve under vacuum condition, and the substrate carrier carries the substrate having the magnetic recording layer after the ashing from the ashing chamber to the CVD chamber.

3. The magnetic recording medium manufacturing device according to claim 1:
wherein the substrate carrier includes;
a substrate holder holding the substrate; and
a driving mechanism driving the substrate holder.

4. The magnetic recording medium manufacturing device according to claim 2:
wherein the substrate carrier includes;
a substrate holder holding the substrate; and
a driving mechanism driving the substrate holder.
